(19) United States
(12) Patent Application Publication
(10) Pub. No.: US 2026/0101735 A1
(43) Pub. Date: Apr. 9, 2026

(54) SEMICONDUCTOR PACKAGE

(71) Applicant: SAMSUNG ELECTRONICS CO., LTD., Suwon-si (KR)

(72) Inventor: HYUNSOO CHUNG, Suwon-si (KR)

(21) Appl. No.: 19/057,533

(22) Filed: Feb. 19, 2025

(30) Foreign Application Priority Data
Aug. 30, 2024 (KR) 10-2024-0118106

(51) Int. Cl. H01L 23/00; H01L 23/31; H01L 23/48; H01L 23/498; H01L 25/00; H01L 25/03; H10B 80/00

(52) U.S. Cl. CPC H10W 20/20; H10W 90/00; H10W 90/701; H10B 80/00; H10W 70/6528; H10W 72/244; H10W 72/874; H10W 72/944; H10W 74/141; H10W 80/743; H10W 90/22; H10W 90/792; H10W 90/794

(57) ABSTRACT

A semiconductor package may include: a device layer including a first semiconductor chip; a second semiconductor chip on the device layer; and a third semiconductor chip on the second semiconductor chip, wherein the device layer further includes: a molding layer surrounding the first semiconductor chip; a redistribution layer on the molding layer; and a conductive post beside the first semiconductor chip, the conductive post vertically penetrating the molding layer and connecting to the redistribution layer, wherein the redistribution layer includes: a first insulating pattern; a power delivery network (PDN) pattern in the first insulating pattern; and a redistribution pad exposed through an upper surface of the first insulating pattern, wherein the second semiconductor chip includes a first chip pad at an inactive surface of the second semiconductor chip, and wherein the PDN pattern is electrically connected to the second semiconductor chip through the redistribution pad and the first chip pad.

### CROSS-REFERENCE TO RELATED APPLICATIONS

This U.S. non-provisional patent application claims priority under 35 U.S.C. §119 of Korean Patent Application No. 10-2024-0118106, filed on Aug. 30, 2024, the entire contents of which are hereby incorporated by reference.

### BACKGROUND

### 1. Field

Embodiments of the present disclosure relate to a semiconductor package and a method for manufacturing the same, and particularly, to a stack-type semiconductor package and a method for manufacturing the same.

### 2. Brief Description of Background Art

In the electronics industry, packaging technology for an integrated circuit is continuously developing in order to satisfy demand for miniaturization and mounting reliability. For example, the demand for miniaturization is accelerating development of technology of a package having a size that is close to a size of a chip, and the demand for mounting reliability is emphasizing importance of the packaging technology that may improve efficiency of mounting, and mechanical and electrical reliability after mounting.

In the electronics industry, since demand of high-capacity, thinning, and miniaturization of a semiconductor package and an electronic product using the semiconductor package increases, various packaging technologies related to the demand are continuously appearing. One of them is obtaining a high-density stacked chip by vertically stacking various semiconductor chips. The technology has an advantage that semiconductor chips respectively having various functions may be integrated in a small area, compared to a general package composed of one semiconductor chip.

A semiconductor package and chips included therein may include a plurality of circuit regions therein. Main electrical characteristics required for elements disposed in each region may differ by region. Meanwhile, when the semiconductor chip and the semiconductor package are highly integrated, it is necessary to form more circuits in a limited chip region. Accordingly, it is necessary to improve reliability by reducing a form factor of the semiconductor chip and the semiconductor package, and simultaneously optimizing the elements disposed in each region.

### SUMMARY

According to embodiments of the present disclosure, a semiconductor package with improved integrity and a method for manufacturing the same are provided.

According to embodiments of the present disclosure, a miniaturized semiconductor package and a method for manufacturing the same are provided.

According to embodiments of the present disclosure, a semiconductor package may be provided and include: a device layer including a first semiconductor chip; a second semiconductor chip on the device layer; and a third semiconductor chip on the second semiconductor chip, wherein the device layer further includes: a molding layer surrounding the first semiconductor chip; a redistribution layer on the molding layer; and a conductive post beside the first semiconductor chip, the conductive post vertically penetrating the molding layer and connecting to the redistribution layer, wherein the redistribution layer includes: a first insulating pattern; a power delivery network (PDN) pattern in the first insulating pattern; and a redistribution pad exposed through an upper surface of the first insulating pattern, wherein the second semiconductor chip includes a first chip pad at an inactive surface of the second semiconductor chip, wherein the PDN pattern is electrically connected to the second semiconductor chip through the redistribution pad and the first chip pad, and wherein the conductive post is electrically connected to the PDN pattern.

According to embodiments of the present disclosure, a semiconductor package may be provided and include: a first semiconductor chip; a molding layer surrounding the first semiconductor chip; a redistribution layer on an upper surface of the molding layer; a second semiconductor chip on the redistribution layer in a face-up form; and a third semiconductor chip on the second semiconductor chip in a face-down form, wherein the redistribution layer includes: a first insulating pattern; a power delivery network (PDN) pattern in the first insulating pattern; and a redistribution pad exposed through an upper surface of the first insulating pattern, wherein the second semiconductor chip includes: a first chip pad at a lower surface of the second semiconductor chip; and a second chip pad at an upper surface of the second semiconductor chip, wherein the third semiconductor chip includes a third chip pad at a lower surface of the third semiconductor chip, wherein an upper surface of the redistribution layer and the lower surface of the second semiconductor chip are in contact with each other, wherein, at an interface of the redistribution layer and the second semiconductor chip, the redistribution pad and the first chip pad are composed of a same material as each other, wherein the upper surface of the second semiconductor chip and the lower surface of the third semiconductor chip are in contact with each other, and wherein the PDN pattern is electrically insulated from the first semiconductor chip, and is electrically connected to the second semiconductor chip.

According to embodiments of the present disclosure, a semiconductor package may be provided and include: a first semiconductor chip; a molding layer surrounding the first semiconductor chip, and on an upper surface of the first semiconductor chip; a redistribution layer in contact with an upper surface of the molding layer; a conductive post beside the first semiconductor chip, the conductive post vertically penetrating the molding layer and connecting to the redistribution layer; a second semiconductor chip in contact with an upper surface of the redistribution layer; a third semiconductor chip on the second semiconductor chip, an active surface of the second semiconductor chip and an active surface of the third semiconductor chip being in contact with each other; and external terminals on a lower surface of the first semiconductor chip and a lower surface of the molding layer, and electrically connected to the conductive post and the first semiconductor chip, wherein a side surface of the molding layer, a side surface of the redistribution layer, a side surface of the second semiconductor chip, and a side surface of the third semiconductor chip are coplanar with each other, wherein the first semiconductor chip includes a chip via penetrating the first semiconductor chip and the molding layer and connected to the redistribution layer, and wherein the redistribution layer includes: a power delivery network (PDN) pattern electrically connected to the second semiconductor chip, and electrically insulated from the first semiconductor chip; and a wiring pattern connected to the chip via.

### BRIEF DESCRIPTION OF DRAWINGS

The accompanying drawings are included to provide a further understanding of embodiments of the present disclosure, and are incorporated in and constitute a part of this specification. The drawings illustrate non-limiting example embodiments of the present disclosure and, together with the description, serve to explain aspects of the present disclosure. In the drawings:

FIG. 1 is a cross-sectional view for describing a semiconductor package according to embodiments of the present disclosure;

FIG. 2 is an enlarged diagram of a region A of FIG. 1;

FIG. 3 is an enlarged diagram of a region B of FIG. 1;

FIGS. 4 to 11 are cross-sectional views for describing a semiconductor package according to embodiments of the present disclosure; and

FIGS. 12 to 20 are cross-sectional views for describing a method for manufacturing a semiconductor package according to embodiments of the present disclosure.

### DETAILED DESCRIPTION

A semiconductor package according to non-limiting example embodiments of the present disclosure will be described below with reference to the drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

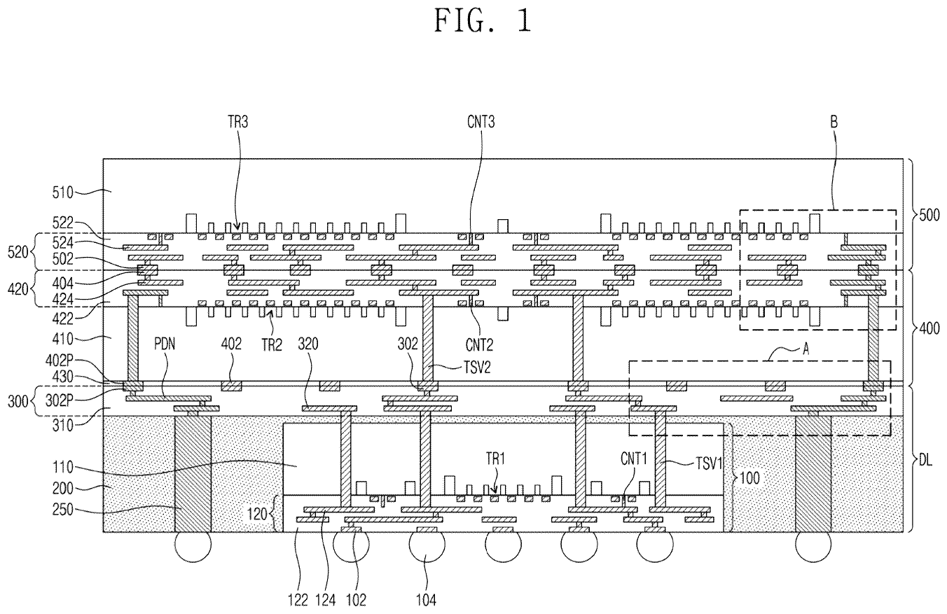

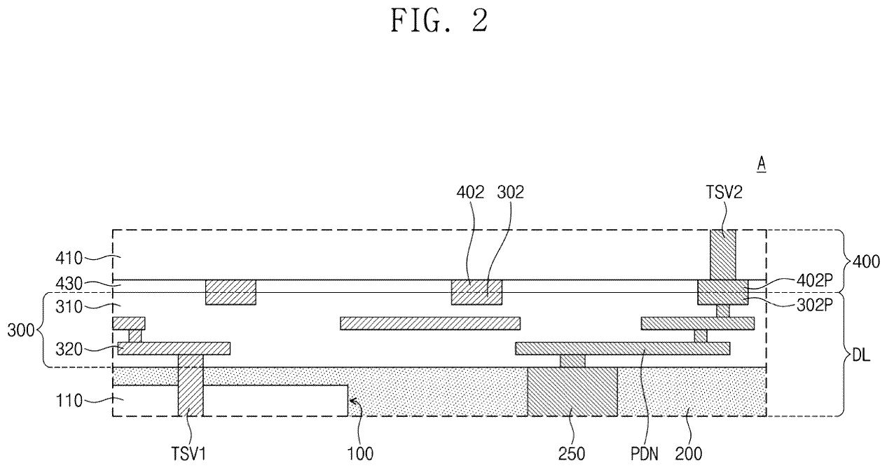

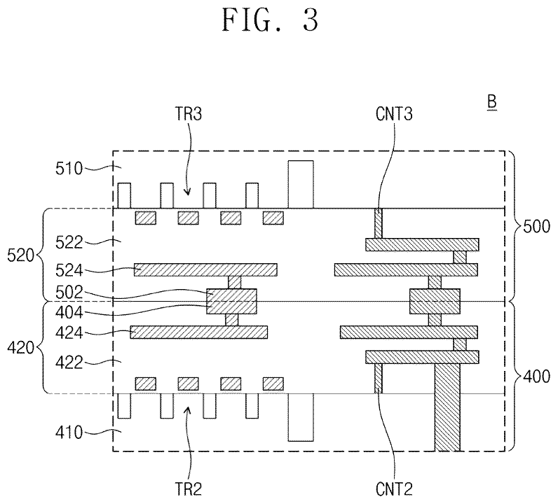

FIG. 1 is a cross-sectional view for describing a semiconductor package according to embodiments of the present disclosure. FIG. 2 is an enlarged diagram of a region A of FIG. 1. FIG. 3 is an enlarged diagram of a region B of FIG. 1.

Referring to FIG. 1, a device layer DL may be provided. The device layer DL may include a first semiconductor chip 100, a molding layer 200, conductive posts 250, and a redistribution layer 300.

The first semiconductor chip 100 may be a wafer-level die made of a semiconductor such as silicon (Si). The first semiconductor chip 100 may include a lower surface. The lower surface of the first semiconductor chip 100 may be a front surface of the first semiconductor chip 100. Hereinafter, in the present specification, the front surface is one surface on which an integrated element or lines in a semiconductor chip are formed, and may be defined as a surface on which pads of the semiconductor chip are formed. A rear surface may be defined as a surface opposite of the front surface. That is, the lower surface of the first semiconductor chip 100 may be an active surface of the first semiconductor chip 100, and an upper surface of the first semiconductor chip 100 may be an inactive surface of the first semiconductor chip 100. In other words, the first semiconductor chip 100 may be disposed in a face-down form.

The first semiconductor chip 100 may include a first semiconductor substrate 110, a first circuit layer 120 disposed on a lower surface of the first semiconductor substrate 110, and first chip vias TSV1 vertically penetrating the first semiconductor substrate 110. A lower surface of the first circuit layer 120 may be the lower surface of the first semiconductor chip 100.

The first semiconductor substrate 110 may include a semiconductor material. For example, the first semiconductor substrate 110 may be a silicon (Si) substrate.

A plurality of first transistors TR1 may be disposed on the first semiconductor substrate 110. More specifically, the first transistors TR1 may be formed on the lower surface of the first semiconductor substrate 110. For example, the first semiconductor chip 100 may be a logic chip. For example, the first transistors TR1 may constitute a logic circuit.

The first circuit layer 120 may cover the lower surface of the first semiconductor substrate 110. The first circuit layer 120 may include a first chip insulating pattern 122 and first chip wiring patterns 124.

The first chip insulating pattern 122 may cover the lower surface of the first semiconductor substrate 110. The first chip insulating pattern 122 may cover the first transistors TR1 on the lower surface of the first semiconductor substrate 110. For example, the first chip insulating pattern 122 may be composed of a multi-layered film including at least one from among silicon oxide (SiO), silicon nitride (SiN), silicon oxynitride (SiON), and a porous insulating film having a low dielectric constant.

The first semiconductor chip 100 may include first chip pads 102 disposed adjacent to the lower surface of the first semiconductor chip 100. The first chip pads 102 may be exposed at (e.g., through) the lower surface of the first semiconductor chip 100, which is the lower surface of the first chip insulating pattern 122, and may be coplanar with the lower surface of the first semiconductor chip 100. The first chip pads 102 may be composed of metal such as copper (Cu).

The first chip wiring patterns 124, which may be multi-layered, may be disposed in the first chip insulating pattern 122. The first transistors TR1, the first chip insulating pattern 122, and the first chip wiring patterns 124 may constitute one circuit layer, that is, the first circuit layer 120. The first transistors TR1 may be electrically connected to the first chip wiring patterns 124 in the first chip insulating pattern 122. For example, the first chip wiring patterns 124 may be connected to the first transistors TR1 through first connection contacts CNT1. The first chip wiring patterns 124 may be electrically connected to the first chip pads 102.

The first chip vias TSV1 penetrating the first semiconductor substrate 110 may be disposed in the first semiconductor substrate 110. The first chip vias TSV1 may partially penetrate the first chip insulating pattern 122 to be electrically connected to the first chip wiring patterns 124 or the first chip pads 102. The first chip vias TSV1 may protrude onto an upper surface of the first semiconductor substrate 110. The first transistors TR1 may be connected to the first chip pads 102 through the first connection contacts CNT1 and the first chip wiring patterns 124, or may be electrically connected to the first chip vias TSV1 through the first connection contacts CNT1 and the first chip wiring patterns 124. The first chip vias TSV1 may include a metal material such as copper (Cu).

The molding layer 200 may be provided. The molding layer 200 may surround the first semiconductor chip 100. That is, the molding layer 200 may cover side surfaces of the first semiconductor chip 100. The molding layer 200 may cover the upper surface of the first semiconductor chip 100. The first chip vias TSV1 may be exposed through an upper surface of the molding layer 200. Upper surfaces of the first chip vias TSV1 may be coplanar with the upper surface of the molding layer 200. The first semiconductor chip 100 may be exposed through a lower surface of the molding layer 200. The lower surface of the first semiconductor chip 100 may be coplanar with the lower surface of the molding layer 200. The molding layer 200 may protect the first semiconductor chip 100. The molding layer 200 may include an insulating material. For example, the molding layer 200 may include an epoxy molding compound (EMC).

The conductive posts 250 may be provided. The conductive posts 250 may be horizontally spaced apart from the first semiconductor chip 100. The conductive posts 250 may have a pillar shape. The conductive posts 250 may vertically penetrate the molding layer 200. For example, the conductive posts 250 may extend toward the upper surface of the molding layer 200 to be exposed through the upper surface of the molding layer 200. The upper surface of the conductive posts 250 may be coplanar with the upper surface of the molding layer 200 and the upper surfaces of the first chip vias TSV1. The conductive posts 250 may extend toward the lower surface of the molding layer 200 to be exposed through the lower surface of the molding layer 200. The conductive posts 250 may include a conductive material. For example, the conductive posts 250 may include a metal material such as copper (Cu) or tungsten (W).

The redistribution layer 300 may be provided on the molding layer 200. The redistribution layer 300 may cover the upper surface of the molding layer 200. A lower surface of the redistribution layer 300 may be in contact with the upper surface of the molding layer 200. The redistribution layer 300 may include at least one lining layer mutually stacked. Each of the lining layers may include a redistribution insulating pattern 310 and a redistribution wiring pattern 320. When the lining layer is provided in plurality, the redistribution wiring pattern 320 of any one lining layer may be electrically connected to the redistribution wiring pattern 320 of another adjacent lining layer. Hereinafter, the redistribution insulating pattern 310 and the redistribution wiring pattern 320 will be described with respect to the one lining layer.

The redistribution insulating pattern 310 may include a photosensitive insulating material (PID). For example, the photosensitive insulating material (PID) may include at least one from among photosensitive polyimide (PI), polybenzoxazole (PBO), phenol-based polymer, and a benzocyclobutene-based polymer. Alternatively, the redistribution insulating pattern 310 may include an insulating material. For example, the redistribution insulating pattern 310 may include silicon oxide (SiO), silicon nitride (SiN), silicon oxynitride (SiON), silicon carbonitride (SiCN), or an insulating polymer.

The redistribution wiring pattern 320 may be provided on the redistribution insulating pattern 310. The redistribution wiring pattern 320 may horizontally extend on the redistribution insulating pattern 310. The redistribution wiring pattern 320 may be a component for redistribution in the substrate. The redistribution wiring pattern 320 may include a conductive material. For example, the redistribution wiring pattern 320 may include copper (Cu) or aluminum (Al).

The redistribution wiring pattern 320 may have a damascene structure. For example, the redistribution wiring pattern 320 may have a head portion and a tail portion integrally connected to each other. The head portion and the tail portion of the redistribution wiring pattern 320 may have a cross-section having a T-shape.

The head portion of the redistribution wiring pattern 320 may be a pad portion or a line portion horizontally extending in the redistribution layer 300. The head portion may be provided on an upper surface of the redistribution insulating pattern 310. For example, the head portion may protrude onto the upper surface of the redistribution insulating pattern 310. The redistribution wiring pattern 320 of an uppermost wiring layer among the wiring layers may be exposed through an upper surface of an uppermost one from among the redistribution insulating patterns 310, that is, an upper surface of the redistribution layer 300. The redistribution wiring pattern 320 that is exposed may be redistribution pads 302 of the redistribution layer 300. Upper surfaces of the redistribution pads 302 may be substantially flat and coplanar with the upper surface of the redistribution insulating pattern 310 of an uppermost wiring layer, that is, the upper surface of the redistribution layer 300.

The tail portion of the redistribution wiring pattern 320 may be a via portion vertically connecting lines in the redistribution layer 300. The tail portion may be connected to another wiring layer disposed thereon. For example, the tail portion of the redistribution wiring pattern 320 may extend from a lower surface of the head portion, and may penetrate the redistribution insulating pattern 310 to be connected to the head portion of the redistribution wiring pattern 320 of another wiring layer disposed thereunder. The tail portion of the redistribution wiring pattern 320 of a lowermost wiring layer among the substrate wiring layers may penetrate the redistribution insulating pattern 310 to be exposed through a lower surface of the redistribution layer 300, that is, a lower surface of the redistribution insulating pattern 310 of the lowermost wiring layer. The redistribution wiring pattern 320 of the lowermost wiring layer may be connected to the upper surface of the first chip vias TSV1. That is, the redistribution wiring pattern 320 may be electrically connected to the first semiconductor chip 100.

A part of the redistribution wiring pattern 320 of the redistribution layer 300 may be a power delivery network pattern PDN for a second semiconductor chip 400 to be described later. The power delivery network pattern PDN may be electrically insulated from the first semiconductor chip 100. That is, the power delivery network pattern PDN may not be connected to the first chip vias TSV1. The power delivery network pattern PDN may penetrate the redistribution insulating pattern 310 to be connected to an upper surface of the conductive posts 250. Redistribution pads 302P connected to the power delivery network pattern PDN, among the redistribution pads 302, may be electrically insulated from the first semiconductor chip 100.

External terminals 104 may be provided under the device layer DL. The external terminals 104 may be connected to the conductive posts 250 and the first chip pads 102 of the first semiconductor chip 100. The external terminals 104 may be disposed on lower surfaces of the first chip pads 102 and lower surfaces of the conductive posts 250. The external terminals 104 may include a solder ball or a solder bump, and a semiconductor package may be provided in a form of a ball grid array (BGA), a fine ball grid array (FBGA), or a land grid array (LGA) depending on a type and an arrangement of the external terminals 104.

The second semiconductor chip 400 may be disposed on the device layer DL. The second semiconductor chip 400 may be a wafer-level die made of semiconductor such as silicon (Si). An upper surface of the device layer DL, that is, an upper surface of the redistribution layer 300, and a lower surface of the second semiconductor chip 400 may be in contact with each other. The second semiconductor chip 400 may vertically overlap the device layer DL. The second semiconductor chip 400 may have a greater width than a width of the first semiconductor chip 100. Side surfaces of the second semiconductor chip 400 may be vertically aligned with side surfaces of the device layer DL. According to some example embodiments, the side surfaces of the second semiconductor chip 400 may be vertically aligned with side surfaces of the molding layer 200 and side surfaces of the redistribution layer 300. An amount of heat generated during driving of the second semiconductor chip 400 may be greater than an amount of heat generated during driving of the first semiconductor chip 100, but embodiments of the present disclosure are not limited thereto.

The first semiconductor chip 100 and the second semiconductor chip 400 may be chip-lets that constitute a logic circuit in the semiconductor package. For example, each of the first semiconductor chip 100 and the second semiconductor chip 400 may be one of chip-lets such as a central processing unit (CPU) element, a graphics processing unit (GPU) element, a display serial interface (DSI) element, a camera serial interface (CSI) element, a modem element, or a power management integrated circuit (PMIC) element. Alternatively, the second semiconductor chip 400 may include a logic chip, a logic chip including a memory element, a logic semiconductor chip including various integrated elements, or a passive element chip.

The second semiconductor chip 400 may include an upper surface. The upper surface of the second semiconductor chip 400 may be a front surface of the second semiconductor chip 400. That is, the upper surface of the second semiconductor chip 400 may be an active surface of the second semiconductor chip 400, and a lower surface of the second semiconductor chip 400 may be an inactive surface of the second semiconductor chip 400. In other words, the second semiconductor chip 400 may be disposed on the device layer DL in a face-up form.

The second semiconductor chip 400 may include a second semiconductor substrate 410, a second circuit layer 420 disposed on an upper surface of the second semiconductor substrate 410, and second chip vias TSV2 vertically penetrating the second semiconductor substrate 410. An upper surface of the second circuit layer 420 may be the upper surface of the second semiconductor chip 400.

The second semiconductor substrate 410 may include a semiconductor material. For example, the second semiconductor substrate 410 may be a silicon (Si) substrate.

A plurality of second transistors TR2 may be disposed on the second semiconductor substrate 410. More specifically, the second transistors TR2 may be formed on the upper surface of the second semiconductor substrate 410. For example, the second semiconductor chip 400 may be a logic chip. For example, the second transistors TR2 may constitute a logic circuit.

The second circuit layer 420 may cover the upper surface of the second semiconductor substrate 410. The second circuit layer 420 may include a second chip insulating pattern 422 and second chip wiring patterns 424.

The second chip insulating pattern 422 may cover the upper surface of the second semiconductor substrate 410. The second chip insulating pattern 422 may cover the second transistors TR2 on the upper surface of the second semiconductor substrate 410. For example, the second chip insulating pattern 422 may be composed of a multi-layered film including at least one from among silicon oxide (SiO), silicon nitride (SiN), silicon oxynitride (SiON), and a porous insulating film having a low dielectric constant.

The second semiconductor chip 400 may include second chip pads 402 disposed adjacent to the lower surface of the second semiconductor chip 400, and third chip pads 404 disposed adjacent to the upper surface of the second semiconductor chip 400. The second chip pads 402 may be disposed on the lower surface of the second semiconductor substrate 410. The third chip pads 404 may be exposed through the upper surface of the second semiconductor chip 400, which is the upper surface of the second chip insulating pattern 422, and may be coplanar with the upper surface of the second semiconductor chip 400. The second chip pads 402 and the third chip pads 404 may be composed of metal such as copper (Cu).

The second chip wiring patterns 424, which may be multilayered, may be disposed in the second chip insulating pattern 422. The second transistors TR2, the second chip insulating pattern 422 and the second chip wiring patterns 424 may constitute one circuit layer, that is, the second circuit layer 420. The second transistors TR2 may be electrically connected to the second chip wiring patterns 424 in the second chip insulating pattern 422. For example, the second chip wiring patterns 424 may be connected to the second transistors TR2 through second connection contacts CNT2. The second chip wiring patterns 424 may be electrically connected to the third chip pads 404.

The second chip vias TSV2 penetrating the second semiconductor substrate 410 may be disposed in the second semiconductor substrate 410. The second chip vias TSV2 may partially penetrate the second chip insulating pattern 422 to be electrically connected to the second chip wiring patterns 424 or the third chip pads 404. The second chip vias TSV2 may penetrate the second semiconductor substrate 410 to be connected to the second chip pads 402. The second transistors TR2 may be connected to the second chip pads 402 through the second connection contacts CNT2 and the second chip wiring patterns 424, or may be electrically connected to the third chip pads 404 through the second connection contacts CNT2, the second chip wiring patterns 424 and the second chip vias TSV2. The second chip vias TSV2 may include a metal material such as copper (Cu).

A rear surface protective film 430 may be disposed on the lower surface of the second semiconductor substrate 410. The rear surface protective film 430 may be an insulating pattern covering the lower surface of the second semiconductor substrate 410. The rear surface protective film 430 may surround the second chip pads 402. The second chip pads 402 may be exposed through a lower surface of the rear surface protective film 430. A lower surface of the second chip pads 402 may be substantially flat and coplanar with the lower surface of the rear surface protective film 430. For example, the rear surface protective film 430 may be composed of a multi-layered film including at least one from among silicon oxide (SiO), silicon nitride (SiN), silicon oxynitride (SiON), and a porous insulating film having a low dielectric constant. Alternatively, the rear surface protective film 430 may include an insulating polymer such as a photosensitive insulating material.

Referring to FIGS. 1 and 2 together, the second semiconductor chip 400 may be directly bonded to the device layer DL. For example, the second chip pads 402 of the second semiconductor chip 400 and the redistribution pads 302 of the redistribution layer 300 may form an intermetallic hybrid bonding at an interface of the redistribution layer 300 and the second semiconductor chip 400. In the present specification, the wording, “a hybrid bonding” means a bonding in which two components including the same material fuse at an interface thereof, or a bonding in which a first component including a first material and a second component including a second material, which is a compound of the first material, fuse at an interface thereof. For example, the second chip pads 402 and the redistribution pads 302 may be in contact with each other, and may have a continuous configuration, and an interface between the second chip pads 402 and the redistribution pads 302 may not be visually seen. The redistribution wiring pattern 320 of the redistribution layer 300 may be electrically connected to the second semiconductor chip 400 through the redistribution pads 302 and the second chip pads 402.

The redistribution insulating pattern 310 of the redistribution layer 300 and the rear surface protective film 430 of the second semiconductor chip 400 may be in contact with each other at the interface of the redistribution layer 300 and the second semiconductor chip 400. An interface of the redistribution insulating pattern 310 and the rear surface protective film 430 may be visually seen, but embodiments of the present disclosure are not limited thereto. The redistribution insulating pattern 310 and the rear surface protective film 430 may be composed of a same material as each other. The redistribution insulating pattern 310 and the rear surface protective film 430 may have a continuous configuration, and an interface between the redistribution insulating pattern 310 and the rear surface protective film 430 may not be visually seen. For example, the redistribution insulating pattern 310 and the rear surface protective film 430 may form a hybrid bonding of an oxide, a nitride, or an oxynitride.

In a bonding of the second semiconductor chip 400 and the device layer DL, second chip pads 402P, from among the second chip pads 402, may be bonded to redistribution pads 302P connected to the power delivery network pattern PDN. The second semiconductor chip 400 may receive a power signal from the outside through the conductive posts 250 and the power delivery network pattern PDN of the redistribution layer 300 of the device layer DL. For example, the redistribution pads 302P connected to the power delivery network pattern PDN, a portion of the second chip pads 402 (e.g., the second chip pads 402P), a portion of the second chip vias TSV2, and a portion of the second chip wiring patterns 424 may provide an electrical path for transmitting the power signal to the second semiconductor chip 400. The electrical path for transmitting the power signal to the second semiconductor chip 400 may be electrically insulated from the first semiconductor chip 100. In other words, the second semiconductor chip 400 may receive the power signal from the conductive posts 250, the power delivery network pattern PDN of the redistribution layer, and the second chip pads 402P.

According to embodiments of the present disclosure, since the logic circuit of the semiconductor package is composed of a plurality of chip-lets, that is, the first semiconductor chip 100 and the second semiconductor chip 400, and the first semiconductor chip 100 and the second semiconductor chip 400 are vertically stacked, a planar area of the semiconductor package may be reduced. In addition, the power delivery network pattern PDN for the second semiconductor chip 400, which may be a chip-let provided at an upper end of the semiconductor package, having a greater area may be provided to the device layer DL in which the first semiconductor chip 100 is provided. Specifically, since the power delivery network pattern PDN is provided in the redistribution layer 300 provided on a rear surface of the first semiconductor chip 100 in the device layer DL, a size and a planar area of the second semiconductor chip 400 may be smaller. That is, a miniaturized semiconductor package may be provided.

In addition, since the second semiconductor chip 400 is connected to the external terminals 104 through the power delivery network pattern PDN and the conductive posts 250, the electrical path for transmitting the power signal to the second semiconductor chip 400 may be shorter. That is, the semiconductor package with improved electrical characteristics may be provided.

In addition, the power delivery network pattern PDN may not be provided in the second circuit layer 420 of the second semiconductor chip 400 having a large amount of heat generated during driving, but may be provided in the redistribution layer 300 of the device layer DL including the first semiconductor chip 100 having a small amount of heat generated during driving. Accordingly, only a small amount of heat generated by the second semiconductor chip 400 may be transmitted to the power delivery network pattern PDN to improve driving stability of the semiconductor package.

Referring back to FIG. 1, a third semiconductor chip 500 may be disposed on the second semiconductor chip 400.

The third semiconductor chip 500 may be a wafer-level die made of a semiconductor such as silicon (Si). An upper surface of the second semiconductor chip 400 and a lower surface of the third semiconductor chip 500 may be in contract with each other. The third semiconductor chip 500 may vertically overlap the device layer DL and the second semiconductor chip 400. Side surfaces of the third semiconductor chip 500 may be vertically aligned (e.g., coplanar) with the side surfaces of the device layer DL and the side surfaces of the second semiconductor chip 400.

The third semiconductor chip 500 may include a logic chip, a memory chip, or a passive element chip.

The third semiconductor chip 500 may include a lower surface. The lower surface of the third semiconductor chip 500 may be a front surface of the third semiconductor chip 500. That is, the lower surface of the third semiconductor chip 500 may be an active surface of the third semiconductor chip 500, and an upper surface of the third semiconductor chip 500 may be an inactive surface of the third semiconductor chip 500. In other words, the third semiconductor chip 500 may be disposed on the second semiconductor chip 400 in a face-down form.

The third semiconductor chip 500 may include a third semiconductor substrate 510 and a third circuit layer 520 disposed on a lower surface of the third semiconductor substrate 510. A lower surface of the third circuit layer 520 may be the upper surface of the third semiconductor chip 500.

The third semiconductor substrate 510 may include a semiconductor material. For example, the third semiconductor substrate 510 may be a silicon (Si) substrate.

A plurality of third transistors TR3 may be disposed on the third semiconductor substrate 510. More specifically, the third transistors TR3 may be formed on the lower surface of the third semiconductor substrate 510. For example, the third semiconductor chip 500 may be a memory chip. For example, the third transistors TR3 may constitute a memory circuit.

The third circuit layer 520 may cover the lower surface of the third semiconductor substrate 510. The third circuit layer 520 may include a third chip insulating pattern 522 and third chip wiring patterns 524.

The third chip insulating pattern 522 may cover the lower surface of the third semiconductor substrate 510. The third chip insulating pattern 522 may cover the third transistors TR3 on the lower surface of the third semiconductor substrate 510. For example, the third chip insulating pattern 522 may be composed of a multi-layered film including at least one from among silicon oxide (SiO), silicon nitride (SiN), silicon oxynitride (SiON), and a porous insulating film having a low dielectric constant.

The third semiconductor chip 500 may include fourth chip pads 502 disposed adjacent to the lower surface of the third semiconductor chip 500. The fourth chip pads 502 may be exposed through the lower surface of the third semiconductor chip 500, which is the lower surface of the third chip insulating pattern 522, and may be coplanar with the upper surface of the third semiconductor chip 500. The fourth chip pads 502 may be composed of metal such as copper (Cu).

The third chip wiring patterns 524, which may be multi-layered, may be disposed in the third chip insulating pattern 522. The third transistors TR3, the third chip insulating pattern 522 and the third chip wiring patterns 524 may constitute one circuit layer, that is, the third circuit layer 520. The third transistors TR3 may be electrically connected to the third chip wiring patterns 524 in the third chip insulating pattern 522. For example, the third chip wiring patterns 524 may be connected to the third transistors TR3 through third connection contacts CNT3. The third chip wiring patterns 524 may be electrically connected to the fourth chip pads 502.

Referring to FIGS. 1 and 3 together, the third semiconductor chip 500 may be directly bonded to the second semiconductor chip 400. For example, the third chip pads 404 of the second semiconductor chip 400 and the fourth chip pads 502 of the third semiconductor chip 500 may form an intermetallic hybrid bonding at an interface of the second semiconductor chip 400 and the third semiconductor chip 500. For example, the third chip pads 404 and the fourth chip pads 502 may be in contact with each other, and may have a continuous configuration, and an interface between the third chip pads 404 and the fourth chip pads 502 may not be visually seen.

The second chip insulating pattern 422 of the second semiconductor chip 400 and the third chip insulating pattern 522 of the third semiconductor chip 500 may be in contact with each other at the interface of the second semiconductor chip 400 and the third semiconductor chip 500. An interface of the second chip insulating pattern 422 and the third chip insulating pattern 522 may be visually seen, but embodiments of the present disclosure are not limited thereto. The second chip insulating pattern 422 and the third chip insulating pattern 522 may be composed of a same material as each other. The second chip insulating pattern 422 and the third chip insulating pattern 522 may have a continuous configuration, and an interface between the second chip insulating pattern 422 and the third chip insulating pattern 522 may not be visually seen. For example, the second chip insulating pattern 422 and the third chip insulating pattern 522 may form a hybrid bonding of an oxide, a nitride, or an oxynitride.

Hereinafter, for convenience of description, duplicate description for technological features described with reference to FIGS. 1 to 3 above may be omitted, and a difference will be described in detail. The same reference numerals or symbols may be provided with respect to the same configurations of the semiconductor package according to embodiments of the present disclosure described above.

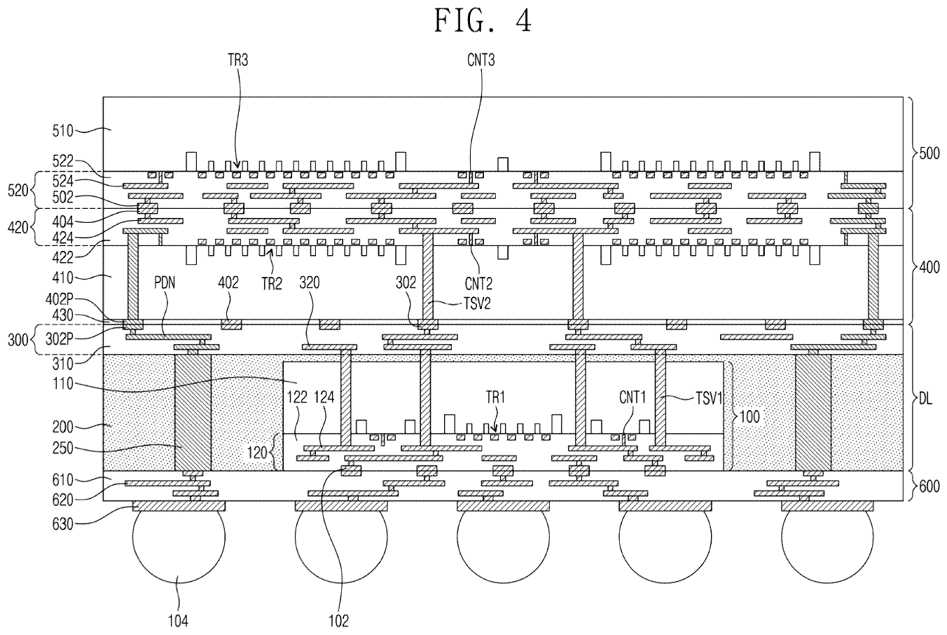

FIG. 4 is a cross-sectional view for describing a semiconductor package according to embodiments of the present disclosure.

Referring to FIG. 4, the semiconductor package may further include an external wiring layer 600. The external wiring layer 600 may be disposed on the lower surface of the device layer DL. The external wiring layer 600 may cover the lower surface of the device layer DL. That is, the external wiring layer 600 may cover a lower surface of the molding layer 200, a lower surface of the first semiconductor chip 100, and a lower surface of the conductive posts 250. Side surfaces of the external wiring layer 600, side surfaces of the device layer DL, side surfaces of the second semiconductor chip 400, and side surfaces of the third semiconductor chip 500 may be vertically aligned (e.g., coplanar) with each other.

The external wiring layer 600 may include at least one wiring layer mutually stacked. Each of the wiring layers may include a substrate insulating pattern 610 and a substrate wiring pattern 620. When the wiring layer is provided in plurality, the substrate wiring pattern 620 of any one wiring layer may be electrically connected to the substrate wiring pattern 620 of another adjacent wiring layer. Hereinafter, the substrate insulating pattern 610 and the substrate wiring pattern 620 will be described with respect to the one wiring layer.

The substrate insulating pattern 610 may include a photosensitive insulating material (PID). For example, the photosensitive insulating material (PID) may include at least one from among photosensitive polyimide (PI), polybenzoxazole (PBO), phenol-based polymer, and benzocyclobutene-based polymer. Alternatively, the substrate insulating pattern 610 may include an insulating material. For example, the substrate insulating pattern 610 may include silicon oxide (SiO), silicon nitride (SiN), silicon oxynitride (SiON), silicon carbonitride (SiCN), or an insulating polymer.

The substrate wiring pattern 620 may be provided on the substrate insulating pattern 610. The substrate wiring pattern 620 may horizontally extend on the substrate insulating pattern 610. The substrate wiring pattern 620 may be a configuration for redistribution in the substrate. The substrate wiring pattern 620 may include a conductive material. For example, the substrate wiring pattern 620 may include copper (Cu) or aluminum (Al).

The substrate wiring pattern 620 may have a damascene structure. For example, the substrate wiring pattern 620 may have a head portion and a tail portion integrally connected to each other. The head portion and the tail portion of the substrate wiring pattern 620 may have a cross-section having a T-shape, or a T-shape turned upside down.

The head portion of the substrate wiring pattern 620 may be a pad portion or a line portion horizontally extending in the external wiring layer 600. The tail portion of the substrate wiring pattern 620 may be a via portion vertically connecting lines in the external wiring layer 600. The tail portion may be connected to another adjacent wiring layer. For example, the tail portion of the substrate wiring pattern 620 may extend from the head portion, and may penetrate the substrate insulating pattern 610 to be connected to the head portion of the substrate wiring pattern 620 of another wiring layer.

The substrate wiring pattern 620 of a lowermost wiring layer among the substrate wiring layers may penetrate the substrate insulating pattern 610 to be connected to a lower surface of the first chip pads 102 of the first semiconductor chip 100 and lower surfaces of the conductive posts 250. That is, the substrate wiring pattern 620 may be electrically connected to the first semiconductor chip 100 and the conductive posts 250.

External pads 630 may be disposed on a lower surface of the external wiring layer 600. The substrate wiring pattern 620 of the external wiring layer 600 may be connected to the external pads 630. The external pads 630 may be pads separately provided on the lower surface of the external wiring layer 600, or may be portions of the substrate wiring pattern 620 exposed through the lower surface of the external wiring layer 600.

The external terminals 104 may be provided under the external wiring layer 600. The external terminals 104 may be connected to the external pads 630.

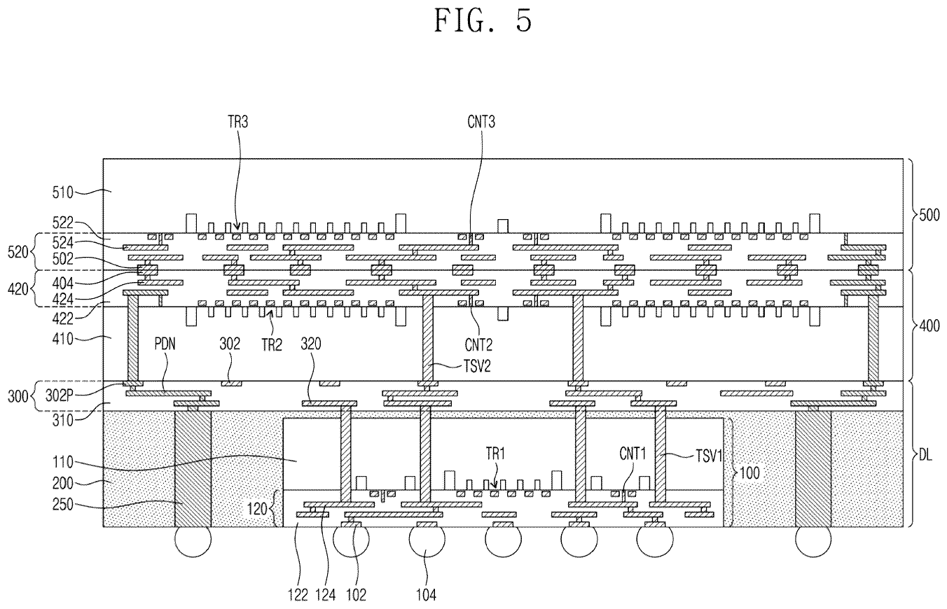

FIG. 5 is a cross-sectional view for describing a semiconductor package according to embodiments of the present disclosure.

Unlike what is described with reference to FIG. 1, the second semiconductor chip 400 of the semiconductor package may not have the second chip pads 402 and the rear surface protective film 430.

Referring to FIG. 5, the second chip vias TSV2 penetrating the second semiconductor substrate 410 may be disposed in the second semiconductor substrate 410. The second chip vias TSV2 may partially penetrate the second chip insulating pattern 422 to be electrically connected to the second chip wiring patterns 424 or the third chip pads 404. The second chip vias TSV2 may penetrate the second semiconductor substrate 410 to be exposed through a lower surface of the second semiconductor substrate 410. Lower surfaces of the second chip vias TSV2 may be substantially flat and coplanar with the lower surface of the second semiconductor substrate 410.

An upper surface of the device layer DL and a lower surface of the second semiconductor chip 400 may be in contact with each other. More specifically, an upper surface of the redistribution layer 300 and the lower surface of the second semiconductor substrate 410 may be in contact with each other.

The second semiconductor chip 400 may be directly bonded to the device layer DL. For example, the second chip vias TSV2 of the second semiconductor chip 400 and the redistribution pads 302 of the redistribution layer 300 may form an intermetallic hybrid bonding at an interface of the redistribution layer 300 and the second semiconductor chip 400. For example, the second chip vias TSV2 and the redistribution pads 302 may be in contact with each other, and may have a continuous configuration, and an interface between the second chip vias TSV2 and the redistribution pads 302 may not be visually seen.

The redistribution insulating pattern 310 of the redistribution layer 300 and the second semiconductor substrate 410 of the second semiconductor chip 400 may be in contact with each other at the interface of the redistribution layer 300 and the second semiconductor chip 400.

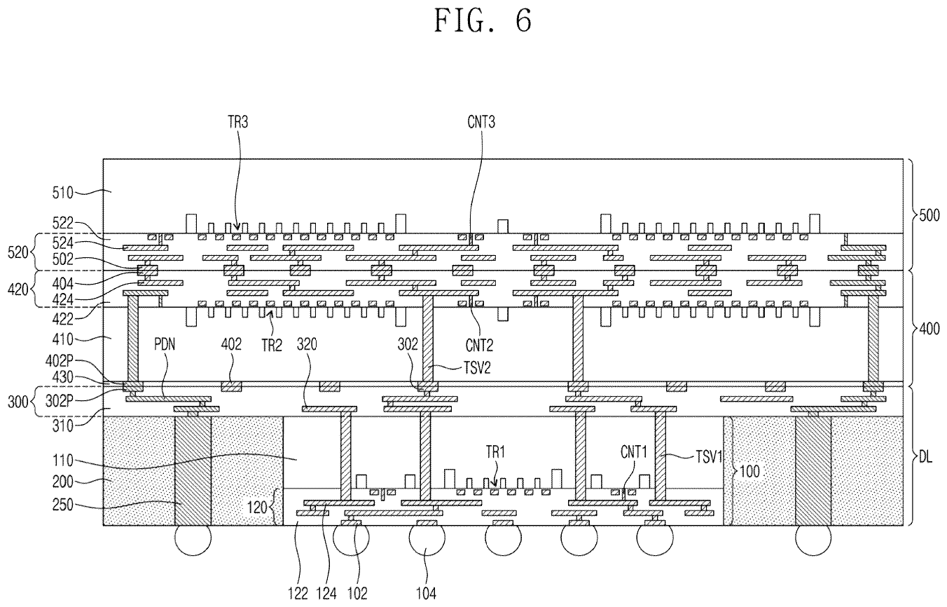

FIG. 6 is a cross-sectional view for describing a semiconductor package according to embodiments of the present disclosure.

Unlike what is described with reference to FIG. 1, the first chip vias TSV1 of the first semiconductor chip 100 of the semiconductor package may not protrude onto an upper surface of the first semiconductor substrate 110.

Referring to FIG. 6, the first chip vias TSV1 penetrating the first semiconductor substrate 110 may be disposed in the first semiconductor substrate 110. The first chip vias TSV1 may partially penetrate the first chip insulating pattern 122 to be electrically connected to the first chip wiring patterns 124 or the first chip pads 102. The first chip vias TSV1 may be exposed through an upper surface of the first semiconductor substrate 110. Upper surfaces of the first chip vias TSV1 may be substantially flat and coplanar with the upper surface of the first semiconductor substrate 110.

The molding layer 200 may surround the first semiconductor chip 100. That is, the molding layer 200 may cover side surfaces of the first semiconductor chip 100. The first semiconductor chip 100 may be exposed through an upper surface of the molding layer 200. The upper surface of the molding layer 200, an upper surface of the first semiconductor chip 100, and upper surfaces of the conductive posts 250 may be substantially flat and coplanar with each other.

The redistribution layer 300 may be provided on the molding layer 200. The redistribution layer 300 may cover the upper surface of the molding layer 200 and the upper surface of the first semiconductor chip 100. A lower surface of the redistribution layer 300 may be in contact with the upper surface of the molding layer 200 and the upper surface of the first semiconductor chip 100. The redistribution wiring pattern 320 of the redistribution layer 300 may be connected to the first chip vias TSV1 exposed through the upper surface of the first semiconductor chip 100 and the conductive posts 250 exposed through the upper surface of the molding layer 200.

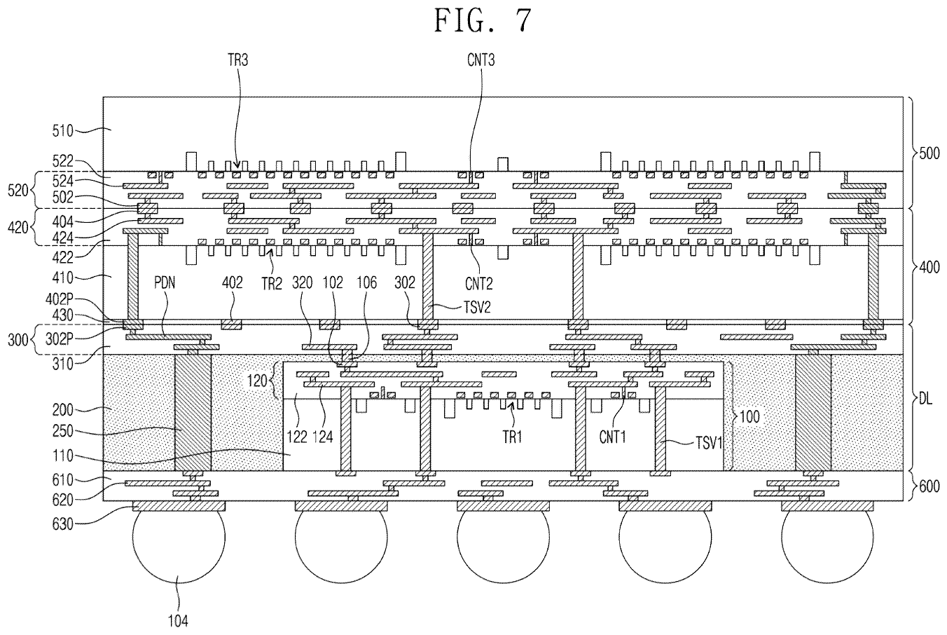

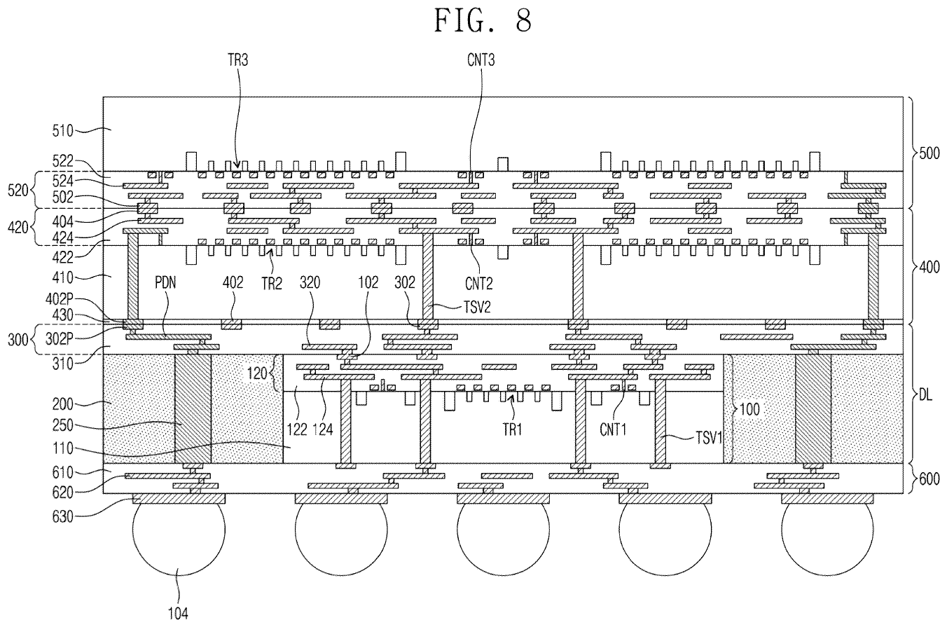

FIGS. 7 and 8 are cross-sectional views for describing a semiconductor package according to embodiments of the present disclosure.

Referring to FIG. 7, the first semiconductor chip 100 may be provided. The first semiconductor chip 100 may include an upper surface. The upper surface of the first semiconductor chip 100 may be a front surface of the first semiconductor chip 100. That is, the upper surface of the first semiconductor chip 100 may be an active surface of the first semiconductor chip 100, and a lower surface of the first semiconductor chip 100 may be an inactive surface of the first semiconductor chip 100. In other words, the first semiconductor chip 100 may be disposed in a face-up form.

The first semiconductor chip 100 may include the first semiconductor substrate 110, the first circuit layer 120 disposed on an upper surface of the first semiconductor substrate 110, and the first chip vias TSV1 vertically penetrating the first semiconductor substrate 110 to be connected to the first circuit layer 120 and to be exposed through a lower surface of the first semiconductor substrate 110. An upper surface of the first circuit layer 120 may be the upper surface of the first semiconductor chip 100.

The first semiconductor chip 100 may include the first chip pads 102 disposed adjacent to the upper surface of the first semiconductor chip 100. The first chip pads 102 may be exposed through the upper surface of the first semiconductor chip 100, which may be an upper surface of the first chip insulating pattern 122.

The first semiconductor chip 100 may further include conductive bumps 106 provided on the upper surface of the first semiconductor chip 100. The conductive bumps 106 may be connected to the first chip pads 102. The conductive bumps 106 may protrude onto an upper surface of the first circuit layer 120.

The molding layer 200 may be provided. The molding layer 200 may surround the first semiconductor chip 100. The molding layer 200 may cover the upper surface of the first semiconductor chip 100. The molding layer 200 may surround the conductive bumps 106 on the upper surface of the first semiconductor chip 100. The conductive bumps 106 may be exposed through an upper surface of the molding layer 200. An upper surface of the conductive bumps 106 may be coplanar with the upper surface of the molding layer 200. The first semiconductor chip 100 may be exposed through a lower surface of the molding layer 200. The lower surface of the first semiconductor chip 100 may be coplanar with the lower surface of the molding layer 200.

The redistribution layer 300 may be provided on the molding layer 200. The redistribution layer 300 may cover the upper surface of the molding layer 200. The redistribution wiring pattern 320 of the redistribution layer 300 may be connected to the conductive posts 250 and the conductive bumps 106 exposed through the upper surface of the molding layer 200.

The external wiring layer 600 may be disposed on the lower surface of the device layer DL. The external wiring layer 600 may cover the lower surface of the device layer DL. That is, the external wiring layer 600 may cover a lower surface of the molding layer 200, a lower surface of the first semiconductor chip 100, and a lower surface of the conductive posts 250. Side surfaces of the external wiring layer 600, side surfaces of the device layer DL, side surfaces of the second semiconductor chip 400, and side surfaces of the third semiconductor chip 500 may be vertically aligned (e.g., coplanar) with each other.

The external wiring layer 600 may be provided on the lower surface of the molding layer 200. The substrate wiring pattern 620 of a lowermost wiring layer among the substrate wiring layers of the external wiring layer 600 may penetrate the substrate insulating pattern 610 to be connected to a lower surface of the first chip vias TSV1 of the first semiconductor chip 100 and lower surfaces of the conductive posts 250.

External pads 630 may be disposed on a lower surface of the external wiring layer 600. The substrate wiring pattern 620 of the external wiring layer 600 may be connected to the external pads 630.

The external terminals 104 may be provided under the external wiring layer 600. The external terminals 104 may be connected to the external pads 630.

According to some embodiments, the first semiconductor chip 100 may not have the conductive bumps 106.

Referring to FIG. 8, the molding layer 200 may be provided. The molding layer 200 may surround the first semiconductor chip 100. The first semiconductor chip 100 may be exposed through the upper surface of the molding layer 200. More specifically, the first circuit layer 120 of the first semiconductor chip 100 may be exposed through the upper surface of the molding layer 200.

The redistribution layer 300 may be provided on the molding layer 200. The redistribution layer 300 may cover the upper surface of the molding layer 200 and an upper surface of the first semiconductor chip 100. The redistribution wiring pattern 320 of the redistribution layer 300 may be connected to the conductive posts 250 and the first chip pads 102.

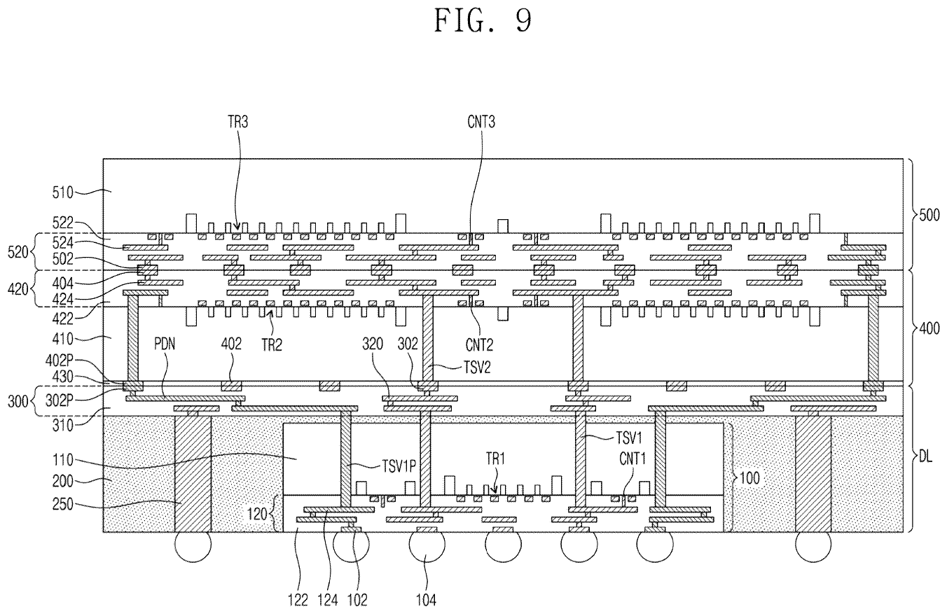

FIG. 9 is a cross-sectional view for describing a semiconductor package according to embodiments of the present disclosure.

Referring to FIG. 9, the power delivery network pattern PDN may be connected to a portion (e.g., a power delivery via TSV1P) of the first chip vias TSV1 of the first semiconductor chip 100. The second semiconductor chip 400 may receive a power signal from the outside through the power delivery via TSV1P and the power delivery network pattern PDN of the redistribution layer 300 of the device layer DL. For example, the redistribution pads 302P connected to the power delivery network pattern PDN, a portion of the second chip pads 402, a portion of the second chip vias TSV2, and a portion of the second chip wiring patterns 424 may provide an electrical path for transmitting the power signal to the second semiconductor chip 400. The electrical path for transmitting the power signal to the second semiconductor chip 400 may be electrically insulated from the first semiconductor chip 100. For example, the power delivery via TSV1P and a portion of the first chip wiring patterns 124 connected to the power delivery via TSV1P may be electrically floated in the first semiconductor chip 100, and may be electrically insulated from an integrated circuit in the first semiconductor chip 100. In other words, the second semiconductor chip 400 may receive the power signal from the power delivery via TSV1P, the power delivery network pattern PDN, and the second chip pads 402P.

The conductive posts 250 may be connected to remaining one(s) of the redistribution wiring patterns 320 of the redistribution layer 300, not the power delivery network pattern PDN.

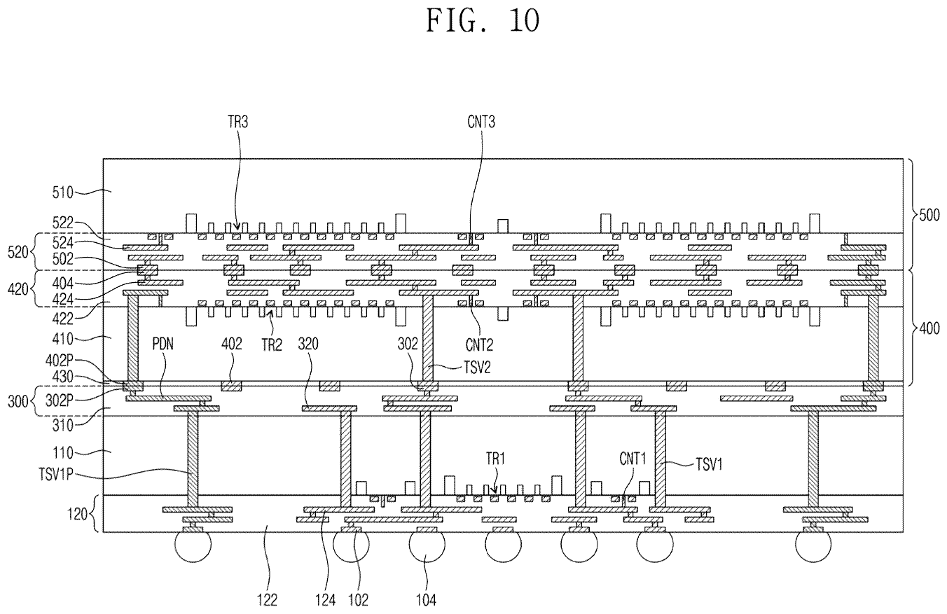

FIG. 10 is a cross-sectional view for describing a semiconductor package according to embodiments of the present disclosure.

Referring to FIG. 10, the device layer DL of the semiconductor package may not have the molding layer and the conductive post. The device layer DL may include the first semiconductor chip 100, and the redistribution layer 300 disposed on the first semiconductor chip 100.

The first semiconductor chip 100 may have the first semiconductor substrate 110, the first circuit layer 120 provided on a lower surface of the first semiconductor substrate 110, and the first chip vias TSV1 vertically penetrating the first semiconductor substrate 110 to be connected to the first circuit layer 120.

The redistribution layer 300 may be provided on an upper surface of the first semiconductor chip 100. The redistribution layer 300 may cover the upper surface of the first semiconductor chip 100. A lower surface of the redistribution layer 300 may be in contact with the upper surface of the first semiconductor chip 100. A portion of the redistribution wiring pattern 320 of the redistribution layer 300 may include a power delivery network pattern PDN for a second semiconductor chip 400 to be described below.

Side surfaces of the first semiconductor chip 100, side surfaces of the redistribution layer 300, side surfaces of the second semiconductor chip 400, and side surfaces of the third semiconductor chip 500 may be vertically aligned (e.g., coplanar) with each other.

The power delivery network pattern PDN may be connected to the power delivery via TSV1P among the first chip vias TSV1 of the first semiconductor chip 100. The second semiconductor chip 400 may receive a power signal from the outside through the power delivery via TSV1P and the power delivery network pattern PDN of the redistribution layer 300 of the device layer DL. The electrical path for transmitting the power signal to the second semiconductor chip 400 may be electrically insulated from the first semiconductor chip 100.

The external terminals 104 may be provided under the first semiconductor chip 100. The external terminals 104 may be connected to the first chip pads 102 of the first semiconductor chip 100. The external terminals 104 may be disposed on a lower surface of the first chip pads 102.

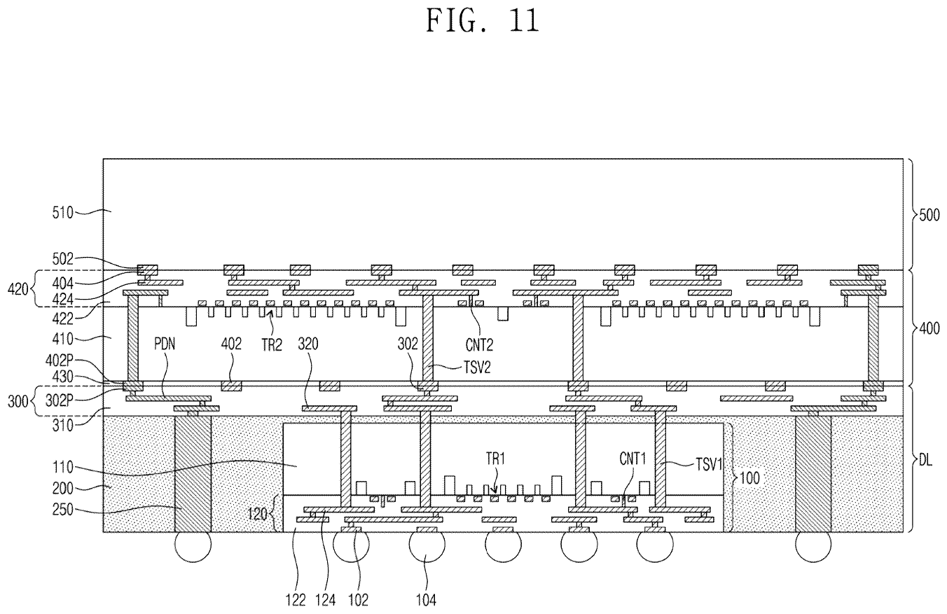

FIG. 11 is a cross-sectional view for describing a semiconductor package according to embodiments of the present disclosure.

Referring to FIG. 11, the third semiconductor chip 500 may include a dummy chip. The third semiconductor chip 500 may include the third semiconductor substrate 510 and the fourth chip pads 502 provided on a lower surface of the third semiconductor substrate 510. The third semiconductor substrate 510 may include a semiconductor material. For example, the third semiconductor substrate 510 may be a silicon (Si) substrate.

The fourth chip pads 502 may be disposed adjacent to a lower surface of the third semiconductor chip 500. The fourth chip pads 502 may be exposed through a lower surface of the third semiconductor substrate 510, and may be coplanar with the lower surface of the third semiconductor substrate 510.

Since the third semiconductor chip 500 is provided as a dummy chip composed of bulk silicon (Si), heat generated by the second semiconductor chip 400 may be easily emitted through the third semiconductor chip 500. That is, the semiconductor package with improved thermal characteristics may be provided.

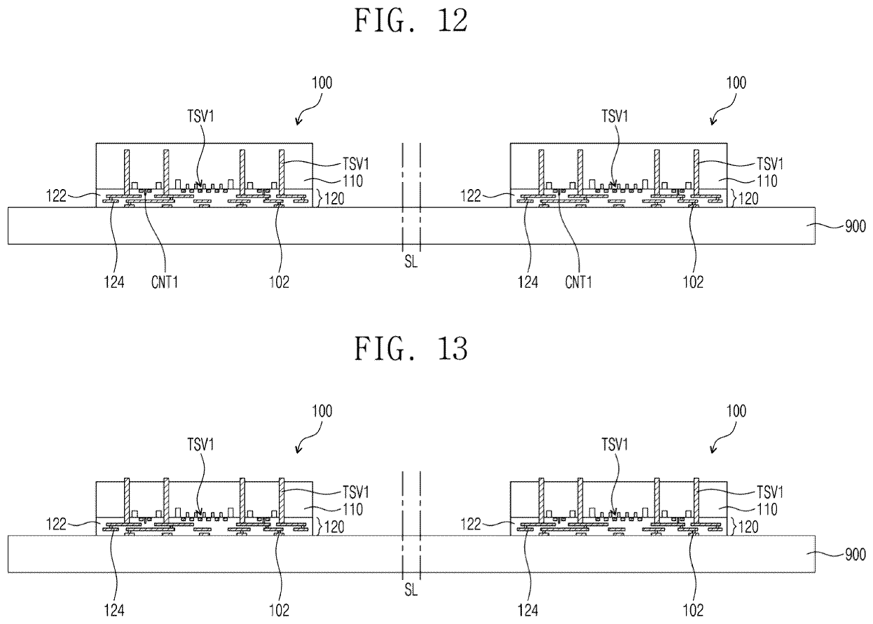

FIGS. 12 to 20 are cross-sectional views for describing a method for manufacturing a semiconductor package according to embodiments of the present disclosure.

Referring to FIG. 12, a carrier substrate 900 may be provided. The carrier substrate 900 may be an insulating substrate including glass or polymer, or a conductive substrate including metal. According to embodiments of the present disclosure, an adhesive member may be provided on an upper surface of the carrier substrate 900. For example, the adhesive member may include an adhesive tape.

The first semiconductor chips 100 may be formed. The first semiconductor chips 100 may be formed through a general process. For example, the first transistors TR1 (see FIG. 1) may be formed on one surface of a semiconductor wafer. The first chip insulating pattern 122 may be formed by depositing an insulating material on the one surface of the semiconductor wafer and then performing a patterning process. The first chip wiring patterns 124 may be formed by depositing a conductive material on the first chip insulating pattern 122 and then performing a patterning process. The first circuit layer 120 may be formed by repeating the above processes. The first chip pads 102 may be formed on a lower surface of the first circuit layer 120. For example, after an opening exposing the first chip wiring patterns 124 is formed by patterning the first chip insulating pattern 122, the first chip pads 102 may be formed by filling the opening with a conductive material. Alternatively, a portion of the first chip wiring patterns 124 exposed through one surface of the first chip insulating pattern 122 may be used as the first chip pads 102.

After via holes are formed in the first semiconductor substrate 110 before, during, or after forming the first circuit layer 120, the first chip vias TSV1 may be formed by filling the via holes with a conductive material. The first chip vias TSV1 may not completely penetrate the semiconductor wafer. The first chip vias TSV1 may not be exposed through the other surface, opposite to the one surface, of the semiconductor wafer.

Thereafter, a plurality of first semiconductor chips 100 may be formed by performing a singulation process on the semiconductor wafer.

The first semiconductor chips 100 may be adhered onto the carrier substrate 900. The first semiconductor chip 100 may be disposed such that the first circuit layer 120 faces the carrier substrate 900.

Referring to FIG. 13, a thinning process may be performed on the first semiconductor chips 100. For example, after a sacrificial film covering the first semiconductor chips 100 is formed on the carrier substrate 900, a grinding process may be performed on the sacrificial film. An upper portion of the first semiconductor substrate 110 of the first semiconductor chips 100 may be partially removed by the thinning process. The thinning process may be performed until the first chip vias TSV1 are exposed. The thinning process may be continuously performed even after upper surfaces of the first chip vias TSV1 are exposed. During the thinning process, the first chip vias TSV1 may not be ground. Accordingly, upper surfaces of the first semiconductor substrates 110 may be lower than the upper surfaces of the first chip vias TSV1. That is, the first chip vias TSV1 may protrude above the upper surfaces of the first semiconductor substrates 110. Thereafter, the sacrificial film may be removed.

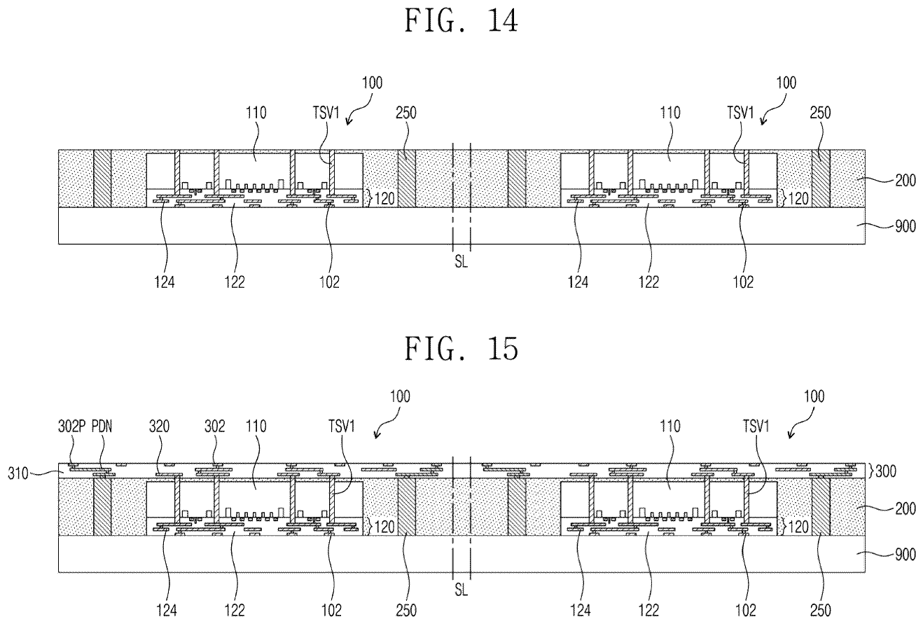

Referring to FIG. 14, the molding layer 200 may be formed on the carrier substrate 900. For example, the molding layer 200 may be formed by applying, on the carrier substrate 900, a molding member covering the first semiconductor chips 100, and then curing the molding member.

Penetration holes vertically penetrating the molding layer 200 may be formed by etching the molding layer 200. The penetration holes may be formed horizontally spaced apart from the first semiconductor chips 100. The conductive posts 250 may be formed by filling the penetration holes with a conductive material. Upper surfaces of the conductive posts 250 may be coplanar with an upper surface of the molding layer 200. For example, a planarization process may be performed on the molding layer 200 and the conductive posts 250.

Referring to FIG. 15, the redistribution layer 300 may be formed on the molding layer 200. For example, an insulating layer may be deposited on the upper surface of the molding layer 200. The redistribution insulating pattern 310 having openings exposing upper surfaces of the conductive posts 250 and upper surfaces of the first chip vias TSV1 may be formed by patterning the insulating layer. A conductive layer may be formed on the redistribution insulating pattern 310. The redistribution wiring pattern 320 may be formed by patterning the conductive layer. One wiring layer having the redistribution insulating pattern 310 and the redistribution wiring pattern 320 may be formed in the above manner. The redistribution layer 300 may be formed by repeatedly performing a process of forming the wiring layer. However, a method for forming the redistribution layer 300 according to embodiments of the present disclosure are not limited thereto, and the redistribution layer 300 may be formed through a general method. A portion, of the redistribution wiring pattern 320, connected to the conductive posts 250 may be the power delivery network pattern PDN.

The redistribution pads 302 may be formed in an uppermost wiring layer. For example, after an opening exposing the redistribution wiring pattern 320 is formed by patterning the redistribution insulating pattern 310 of the uppermost wiring layer, the redistribution pads 302 may be formed by filling the opening with a conductive material. In this case, redistribution pads 302P, from among the redistribution pads 302, may be connected to the power delivery network pattern PDN.

Referring to FIG. 16, the second semiconductor chips 400 may be formed. More specifically, a first wafer WF1 may be provided. The first wafer WF1 may be a semiconductor wafer. For example, the first wafer WF1 may be a silicon (Si) wafer. The second transistors TR2 may be formed on one surface of the first wafer WF1. The second chip insulating pattern 422 may be formed by depositing an insulating material on the one surface of the first wafer WF1 and then performing a patterning process. The second chip wiring patterns 424 may be formed by depositing a conductive material on the second chip insulating pattern 422 and then performing a patterning process. The second circuit layer 420 may be formed by repeating the above processes. The third chip pads 404 may be formed at (e.g., in or on) an upper surface of the second circuit layer 420. For example, after an opening exposing the second chip wiring patterns 424 is formed by patterning the second chip insulating pattern 422, the third chip pads 404 may be formed by filling the opening with a conductive material. Alternatively, a portion of the second chip wiring patterns 424 exposed through one surface of the second chip insulating pattern 422 may be used as the third chip pads 404.

After via holes are formed in the first wafer WF1 before, during, or after forming the second circuit layer 420, the second chip vias TSV2 may be formed by filling the via holes with a conductive material. Thereafter, a thinning process may be performed on the other surface, opposite to the one surface, of the first wafer WF1. Accordingly, the second chip vias TSV2 may be exposed through the other surface of the first wafer WF1.

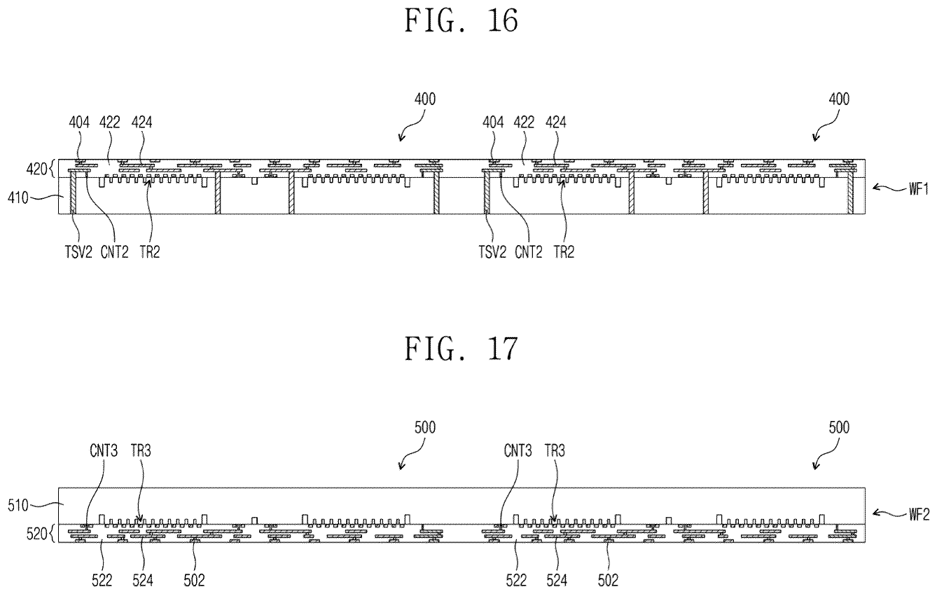

Referring to FIG. 17, the third semiconductor chips 500 may be formed. More specifically, a second wafer WF2 may be provided. The second wafer WF2 may be a semiconductor wafer. For example, the second wafer WF2 may be a silicon (Si) wafer. The third transistors TR3 may be formed on one surface of the second wafer WF2. The third chip insulating pattern 522 may be formed by depositing an insulating material on the one surface of the second wafer WF2 and then performing a patterning process. The third chip wiring patterns 524 may be formed by depositing a conductive material on the third chip insulating pattern 522 and then performing a patterning process. The third circuit layer 520 may be formed by repeating the above processes. The fourth chip pads 502 may be formed at (e.g., in or on) a lower surface of the third circuit layer 520. For example, after an opening exposing the third chip wiring patterns 524 is formed by patterning the third chip insulating pattern 522, the fourth chip pads 502 may be formed by filling the opening with a conductive material. Alternatively, a portion of the third chip wiring patterns 524 exposed through one surface of the third chip insulating pattern 522 may be used as the fourth chip pads 502.

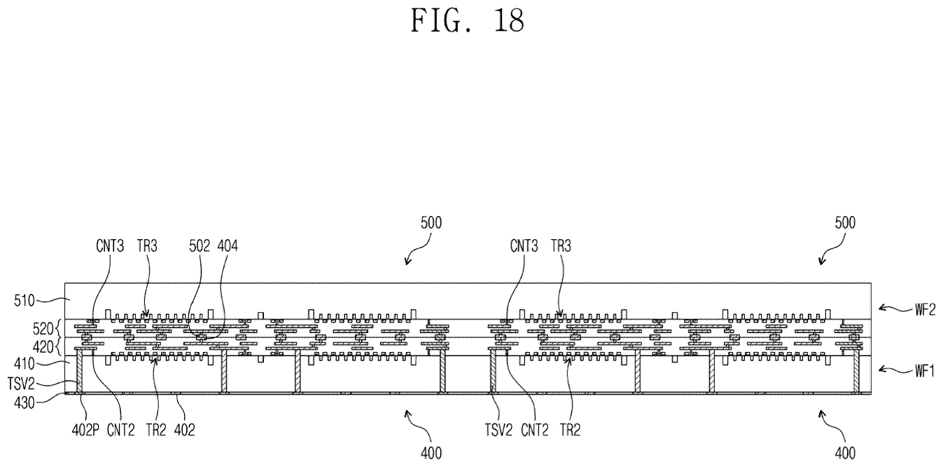

Referring to FIG. 18, the second wafer WF2 may be adhered onto the first wafer WF1.

The second wafer WF2 may be aligned with the first wafer WF1 such that the fourth chip pads 502 of the third semiconductor chip 500 are located on the third chip pads 404 of the second semiconductor chip 400. The second wafer WF2 may be disposed on the first wafer WF1 such that the fourth chip pads 502 are in contact with the third chip pads 404. A heat-treatment process may be performed on the second wafer WF2. The fourth chip pads 502 and the third chip pads 404 may be bonded to each other by the heat-treatment process. For example, the fourth chip pads 502 and the third chip pads 404 may be coupled to each other, and may be integrally formed. The third chip pads 404 and the fourth chip pads 502 may be naturally coupled to each other. Specifically, the fourth chip pads 502 and the third chip pads 404 may be composed of the same material (e.g., copper (Cu) or the like), and may be coupled to each other by an intermetallic hybrid bonding process by surface activation on an interface of the fourth chip pads 502 and the third chip pads 404 in contact with each other.

The rear surface protective film 430 may be formed on a lower surface of the first wafer WF1. For example, the rear surface protective film may be formed by applying or depositing an insulating material on the lower surface of the first wafer WF1.

The second chip pads 402 may be formed. For example, after an opening is formed by patterning the rear surface protective film 430, the second chip pads 402 may be formed by filling the opening with a conductive material.

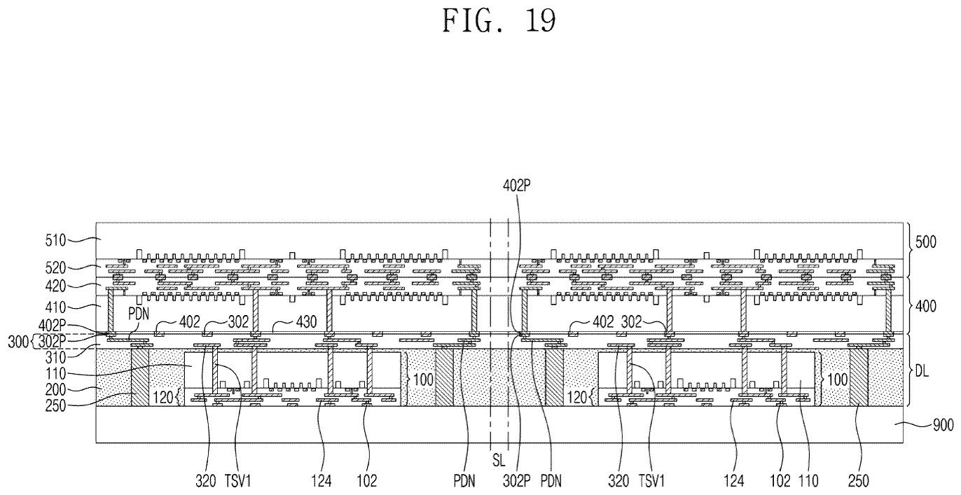

Referring to FIG. 19, the first wafer WF1 may be adhered onto the device layer DL.

The first wafer WF1 may be aligned with the device layer DL such that the second chip pads 402 of the first wafer WF1 are located on the redistribution pads 302 of the redistribution layer 300. The first wafer WF1 may be disposed on the device layer DL such that the second chip pads 402 are in contact with the redistribution pads 302. A heat-treatment process may be performed on the first wafer WF1. The redistribution pads 302 and the second chip pads 402 may be bonded to each other by the heat-treatment process. For example, the second chip pads 402 and the redistribution pads 302 may be coupled to each other, and may be integrally formed. The second chip pads 402 and the redistribution pads 302 may be naturally coupled to each other. Specifically, the redistribution pads 302 and the second chip pads 402 may be composed of the same material (e.g., copper (Cu) or the like), and may be coupled to each other by an intermetallic hybrid bonding process by surface activation on an interface of the redistribution pads 302 and the second chip pads 402 in contact with each other.

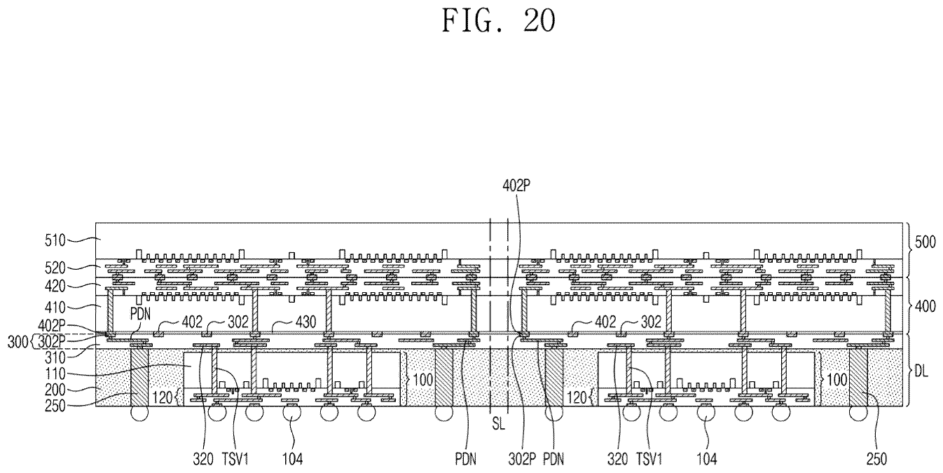

Referring to FIG. 20, the carrier substrate 900 may be removed. Accordingly, a lower surface of the device layer DL may be exposed. More specifically, lower surfaces of the first semiconductor chips 100, lower surfaces of the conductive posts 250, and a lower surface of the molding layer 200 may be exposed.

The external terminals 104 may be provided on a lower surface of the device layer DL. The external terminals 104 may be connected to the lower surfaces of the first chip pads 102 and the lower surfaces of the conductive posts 250.

Thereafter, the semiconductor packages may be separated from each other by cutting the third semiconductor chip 500, the second semiconductor chip 400, the redistribution layer 300, and the molding layer 200 along a sawing line SL.

A semiconductor package according to embodiments of the present disclosure is configured by dividing a logic circuit in the semiconductor package into a plurality of semiconductor chips, and a planar area of the semiconductor package may be small by vertically stacking the semiconductor chips. In addition, a power delivery network pattern for a semiconductor chip provided at an upper end of the semiconductor package, and having a greater area may be provided on a device layer in which a semiconductor chip of a lower end of the semiconductor package is provided. Accordingly, the semiconductor chip of the upper end may have a smaller size and a smaller planar area. That is, a miniaturized semiconductor package may be provided.

In addition, since a second semiconductor chip is connected to external terminals through the power delivery network pattern and conductive posts, an electrical path for transmitting a power signal to the second semiconductor chip may be short. That is, the semiconductor package with improved electrical characteristics may be provided.

In addition, the power delivery network pattern may be provided in a redistribution layer of the device layer including a first semiconductor chip having a small amount of heat generated during driving, not a second circuit layer of the second semiconductor chip having a greater amount of heat generated during driving. Accordingly, only a small amount of heat generated by the second semiconductor chip may be transmitted to the power delivery network pattern to improve driving stability of the semiconductor package.

Although non-limiting example embodiments of the present disclosure have been described above with reference to the accompanying drawings, it is understood that embodiments of the present disclosure are not limited to these example embodiments, and various changes and modifications can be made by one ordinary skilled in the art within the spirit and scope of the present disclosure.

What is claimed is:

1. A semiconductor package comprising:
a device layer comprising a first semiconductor chip;
a second semiconductor chip on the device layer; and
a third semiconductor chip on the second semiconductor chip,
wherein the device layer further comprises:
a molding layer surrounding the first semiconductor chip;
a redistribution layer on the molding layer; and
a conductive post beside the first semiconductor chip, the conductive post vertically penetrating the molding layer and connecting to the redistribution layer,
wherein the redistribution layer comprises:
a first insulating pattern;
a power delivery network (PDN) pattern in the first insulating pattern; and
a redistribution pad exposed through an upper surface of the first insulating pattern,
wherein the second semiconductor chip comprises a first chip pad at an inactive surface of the second semiconductor chip,
wherein the PDN pattern is electrically connected to the second semiconductor chip through the redistribution pad and the first chip pad, and
wherein the conductive post is electrically connected to the PDN pattern.

2. The semiconductor package of claim 1, wherein the redistribution layer and the inactive surface of the second semiconductor chip are in contact with each other, and
wherein, at an interface of the redistribution layer and the second semiconductor chip, the redistribution pad and the first chip pad are composed of a same material as each other.

3. The semiconductor package of claim 1, wherein the second semiconductor chip further comprises a second insulating pattern on the inactive surface of the second semiconductor chip,
wherein the first chip pad is exposed through a lower surface of the second insulating pattern, and
wherein the first insulating pattern and the second insulating pattern are in contact with each other.

4. The semiconductor package of claim 1, wherein the PDN pattern is electrically insulated from the first semiconductor chip.

5. The semiconductor package of claim 1, wherein the second semiconductor chip comprises a second chip pad at an active surface of the second semiconductor chip,
wherein the third semiconductor chip comprises a third chip pad at an active surface of the third semiconductor chip,
wherein the active surface of the second semiconductor chip and the active surface of the third semiconductor chip are in contact with each other, and
wherein, at an interface of the second semiconductor chip and the third semiconductor chip, the second chip pad and the third chip pad are composed of a same material as each other.

6. The semiconductor package of claim 1, wherein the first semiconductor chip comprises chip vias penetrating the first semiconductor chip and electrically connected to the redistribution layer.

7. The semiconductor package of claim 6, wherein the redistribution layer further comprises a wiring pattern in the first insulating pattern and electrically connected to the chip vias, and
wherein the wiring pattern is electrically connected to the second semiconductor chip.

8. The semiconductor package of claim 6, wherein an active surface of the first semiconductor chip is exposed through a lower surface of the molding layer,
wherein the molding layer is on an inactive surface of the first semiconductor chip, and
wherein the chip vias penetrate the first semiconductor chip and the molding layer and are connected to the redistribution layer.

9. The semiconductor package of claim 1, wherein an inactive surface of the first semiconductor chip is exposed through a lower surface of the molding layer,
wherein the molding layer is on an active surface of the first semiconductor chip, and
wherein the first semiconductor chip further comprises bumps on the active surface of the first semiconductor chip, exposed through an upper surface of the molding layer, and connected to the redistribution layer.

10. The semiconductor package of claim 1, wherein the device layer further comprises:
an external wiring layer on a lower surface of the molding layer and a lower surface of the first semiconductor chip; or
external terminals on the lower surface of the first semiconductor chip.

11. The semiconductor package of claim 1, wherein a side surface of the molding layer, a side surface of the second semiconductor chip, and a side surface of the third semiconductor chip are coplanar with each other.

12. The semiconductor package of claim 1, wherein the second semiconductor chip comprises a logic chip, and
wherein the third semiconductor chip comprises a memory chip.

13. A semiconductor package comprising:
a first semiconductor chip;
a molding layer surrounding the first semiconductor chip;
a redistribution layer on an upper surface of the molding layer;
a second semiconductor chip on the redistribution layer in a face-up form; and
a third semiconductor chip on the second semiconductor chip in a face-down form,
wherein the redistribution layer comprises:
a first insulating pattern;
a power delivery network (PDN) pattern in the first insulating pattern; and
a redistribution pad exposed through an upper surface of the first insulating pattern,
wherein the second semiconductor chip comprises:
a first chip pad at a lower surface of the second semiconductor chip; and
a second chip pad at an upper surface of the second semiconductor chip,
wherein the third semiconductor chip comprises a third chip pad at a lower surface of the third semiconductor chip,
wherein an upper surface of the redistribution layer and the lower surface of the second semiconductor chip are in contact with each other,
wherein, at an interface of the redistribution layer and the second semiconductor chip, the redistribution pad and the first chip pad are composed of a same material as each other,
wherein the upper surface of the second semiconductor chip and the lower surface of the third semiconductor chip are in contact with each other, and
wherein the PDN pattern is electrically insulated from the first semiconductor chip, and is electrically connected to the second semiconductor chip.

14. The semiconductor package of claim 13, wherein the second semiconductor chip further comprises a second insulating pattern,
wherein the first chip pad is exposed through a lower surface of the second insulating pattern, and
wherein the first insulating pattern and the second insulating pattern are in contact with each other.

15. The semiconductor package of claim 13, wherein, at an interface of the second semiconductor chip and the third semiconductor chip, the second chip pad and the third chip pad are composed of a same material as each other.

16. The semiconductor package of claim 13, wherein the molding layer is on an upper surface of the first semiconductor chip, and
the first semiconductor chip comprises chip vias penetrating the first semiconductor chip and the molding layer, and connected to the redistribution layer.

17. The semiconductor package of claim 13, further comprising a conductive post beside the first semiconductor chip, the conductive post vertically penetrating the molding layer and connected to the redistribution layer,
wherein the conductive post is electrically connected to the PDN pattern.

18. The semiconductor package of claim 13, further comprising:
an external wiring layer on a lower surface of the molding layer and a lower surface of the first semiconductor chip; or
external terminals on the lower surface of the first semiconductor chip.

19. The semiconductor package of claim 13, wherein a side surface of the molding layer, a side surface of the second semiconductor chip, and a side surface of the third semiconductor chip are coplanar with each other.

20. A semiconductor package comprising:
a first semiconductor chip;
a molding layer surrounding the first semiconductor chip, and on an upper surface of the first semiconductor chip;
a redistribution layer in contact with an upper surface of the molding layer;
a conductive post beside the first semiconductor chip, the conductive post vertically penetrating the molding layer and connecting to the redistribution layer;
a second semiconductor chip in contact with an upper surface of the redistribution layer;
a third semiconductor chip on the second semiconductor chip, an active surface of the second semiconductor chip and an active surface of the third semiconductor chip being in contact with each other; and
external terminals on a lower surface of the first semiconductor chip and a lower surface of the molding layer, and electrically connected to the conductive post and the first semiconductor chip,
wherein a side surface of the molding layer, a side surface of the redistribution layer, a side surface of the second semiconductor chip, and a side surface of the third semiconductor chip are coplanar with each other,
wherein the first semiconductor chip comprises a chip via penetrating the first semiconductor chip and the molding layer and connected to the redistribution layer, and
wherein the redistribution layer comprises:
a power delivery network (PDN) pattern electrically connected to the second semiconductor chip, and electrically insulated from the first semiconductor chip; and
a wiring pattern connected to the chip via.
